(19) United States
(12) Patent Application Publication
(10) Pub. No.: US 2010/0155860 A1
(43) Pub. Date: Jun. 24, 2010

(54) TWO STEP METHOD TO CREATE A GATE ELECTRODE USING A PHYSICAL VAPOR DEPOSITED LAYER AND A CHEMICAL VAPOR DEPOSITED LAYER

(75) Inventors: Luigi Colombo, Dallas, TX (US); James J. Chambers, Dallas, TX (US); Mark R. Visokay, Wappingers Falls, NY (US); Majid Mansoori, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/344,046

(22) Filed: Dec. 24, 2008

(51) Int. Cl. H01L 29/43; H01L 21/283; H01L 21/336; C23C 14/34

(52) U.S. Cl. 257/412; 438/592; 438/283; 204/192.1; 257/E29.139; 257/E21.159; 257/E21.409

(57) ABSTRACT

One embodiment of the present invention relates a semiconductor device formed by utilizing a two step deposition method for forming a gate electrode without causing damages to an underlying gate dielectric material. In one embodiment, a first layer of gate electrode material (first gate electrode layer) is formed onto the surface of a gate dielectric material using a deposition that does not damage the gate dielectric material (e.g., physical vapor deposition) thereby resulting in a damage free interface between the gate dielectric material and the gate electrode material. A second layer of gate electrode material (second gate electrode layer) is then formed onto the first layer of gate electrode material using a chemical deposition method that provides increased deposition control (e.g., good layer uniformity, impurity control, etc.). The first and second gate electrode layers are then selectively patterned to cumulatively form a semiconductor device's gate electrode.

### FIELD OF INVENTION

The present invention relates generally to semiconductor device fabrication and more particularly to a two step method of forming a gate electrode layer.

### BACKGROUND OF THE INVENTION

Semiconductor devices, such as metal-oxide semiconductor field-effected transistors (MOSFET) utilize a gate electrode to control a charge carrying channel adjoining a source and a drain. The channel, source, and drain are located in a semiconductor body with the source and drain being counter doped relative to the surrounding substrate. The gate is separated from the semiconductor body by a thin dielectric material often referred to as a gate oxide. The gate oxide insulates the gate electrode from the charge carrying channel thereby allowing charge to go from the source to the drain of the device.

The physical qualities of a gate oxide and gate electrode directly affect electrical parameters of an associated MOSFET device. For example, a gate oxide's thickness is directly related to the capacitance of the gate oxide layer (i.e., C=k∈ₒ/t, where C is the gate capacitance per unit area, k is the permittivity of the oxide, ∈ₒ is the permittivity of free space, and t is the gate oxide thickness) and the capacitance subsequently effects such performance parameters as the threshold voltage of an associated device.

During processing, the gate oxide is formed on a semiconductor body (e.g., a silicon wafer). A gate electrode material is subsequently formed on top of gate oxide. Often the gate electrode material is deposited onto the gate oxide using a chemical vapor deposition process. Chemical vapor deposition (CVD) is a process by which a film is formed on a substrate from the reaction of vapor phase chemical reactants comprising predetermined constituents. CVD is performed in a reaction chamber, into which the reactant gases are introduced to decompose and react with the substrate to form the film.

During a basic CVD process a predetermined mix of reactant gases and diluent inert gases are introduced at a specified flow rate into the reaction chamber. The gas species move to the substrate, where the reactants are adsorbed on the surface of the substrate. At the surface of the substrate the reactants undergo chemical reactions with the substrate to form a film. The reactions that take place at the substrate surface are known as heterogeneous reactions, and occur on the surface of the wafer where they create good-quality films. Once the film is formed to a desired thickness the process is ended and the gaseous by-products of the reactions are evacuated from the reaction chamber.

### SUMMARY OF THE INVENTION

The following presents a simplified summary in order to provide a basic understanding of one or more aspects of the invention. This summary presents one or more concepts of the invention in a simplified form as a prelude to the more detailed description that is presented later and is not an extensive overview of the invention. In this regard, the summary is not intended to identify key or critical elements of the invention, nor does the summary delineate the scope of the invention.

One embodiment of the present invention relates a semiconductor device formed by utilizing a two step deposition method for forming a gate electrode without causing damage to an underlying gate dielectric material. In one embodiment, a first layer of gate electrode material (first gate electrode layer) is formed onto the surface of a gate dielectric material using a deposition that does not damage the gate dielectric material (e.g., physical vapor deposition) thereby resulting in a damage free interface between the gate dielectric material and the gate electrode material. A second layer of gate electrode material (second gate electrode layer) is then formed onto the first layer of gate electrode material using a chemical deposition method that provides increased deposition control (e.g., good layer uniformity, impurity control, etc.). The first and second gate electrode layers are then selectively patterned to cumulatively form a semiconductor device's gate electrode. Therefore, the method provided herein provides a high quality gate electrode material without damaging the underlying gate electrode material thereby resulting in an improvement in device characteristics and integrated chip reliability.

The following description and annexed drawings set forth in detail certain illustrative aspects and implementations of the invention. These are indicative of but a few of the various ways in which the principles of the invention may be employed.

### BRIEF DESCRIPTION OF THE DRAWINGS

FIG. 1 illustrates a CMOS transistor comprising a gate electrode having a physically deposited layer and a chemically deposited layer;

FIG. 2 is a flow diagram illustrating a two step method of forming a gate electrode layer; and

FIGS. 3-11 illustrate cross sectional views of a semiconductor body wherein one or more MOS transistors are formed according to the method of FIG. 2.

### DETAILED DESCRIPTION OF THE INVENTION

The present invention will now be described with reference to the attached drawing figures, wherein like reference numerals are used to refer to like elements throughout, and wherein the illustrated structures and devices are not necessarily drawn to scale.

Complementary metal-oxide-semiconductor (CMOS) technology is the dominant semiconductor technology used for the manufacture of ultra-large scale integrated (ULSI) circuits today. Current CMOS transistors typically utilize polysilicon as the gate electrode for both NMOS and PMOS transistors, wherein the polysilicon is doped with an N-type dopant to form NMOS transistors and is doped with a P-type dopant to form PMOS transistors. Polysilicon gates often exhibit a large depletion region above the gate.

Over the past 30 years increasingly powerful integrated chips have been formed by shrinking the dimension of semiconductor devices. Scaling semiconductor devices provides improved performance. As transistor size decreases, this depletion region has become and increasing problem, leading to poor device performance. In particular, the polysilicon in gate electrodes brings about the increasing effective thickness of a gate dielectric layer due to gate depletion effect. Therefore, in emerging technology nodes (e.g., 45 nm, 32 nm, 22 nm) semiconductor fabrication corporations have looked to forming CMOS transistors with metal gates. Metal gates allow increased carrier concentration in the electrode and therefore do not suffer from a large depletion region above the gate.

However, deposition of metal gates by a chemical means such as chemical vapor deposition (CVD) or atomic layer deposition (ALD) can introduce unwanted impurities at the interface of the dielectric layer and gate metal layer. These unwanted impurities can cause damage to the underlying gate dielectrics (e.g., gate oxide). For example, gate dielectric materials undergo degradation due to attack from atomic/molecular hydrogen during gate electrode deposition performed by chemical vapor deposition (CVD) using SiH₄. Such gate dielectric damage creates defects at the interface between the gate dielectric material and the gate electrode material which can affect the electrical properties of the device. The resultant effect of the damage will likely become larger as device sizes decrease due to the relative effect of defects on a scaled gate dielectric material. For example, damage to the thinner gate dielectric layers will have an increased effect on subthreshold leakage current, static power consumption, yield, and device reliability since the defects constitute a larger percentage of the gate dielectric thickness. Accordingly, there is a need for a method to produce a high quality metal gate electrode layer without damaging an underlying gate dielectric layer.

The present invention relates a semiconductor device formed by utilizing a two step deposition method for forming a gate electrode without causing damage to an underlying gate dielectric material. As provided herein, a gate electrode (e.g., metal gate electrode) comprises two distinct metal layers. A first gate metal layer is deposited onto an underlying gate dielectric layer at a first interface (i.e., gate dielectric/first gate electrode layer interface) using a physical deposition process (e.g., evaporation process) that is non-damaging to the underlying gate dielectric. A second gate metal layer is then deposited on top the first gate metal layer at a second interface (i.e., first gate electrode layer/second gate electrode layer interface) using a chemical deposition process. The first gate metal layer protects the gate dielectric layer by minimizing disturbances from the chemical deposition process at the gate dielectric/electrode interface and thereby preventing damage the gate dielectric layer.

The resultant gate electrode formed according to the two step deposition process controls impurities (hydrogen, carbon, oxygen, etc.) in the interface between the first gate metal layer and dielectric layer, as well as within the dielectric layer (e.g., through interdiffusion). Through selective impurity control, the deposited gate metal layers stack sets the work function on top of the gate to control the threshold voltage of the device.

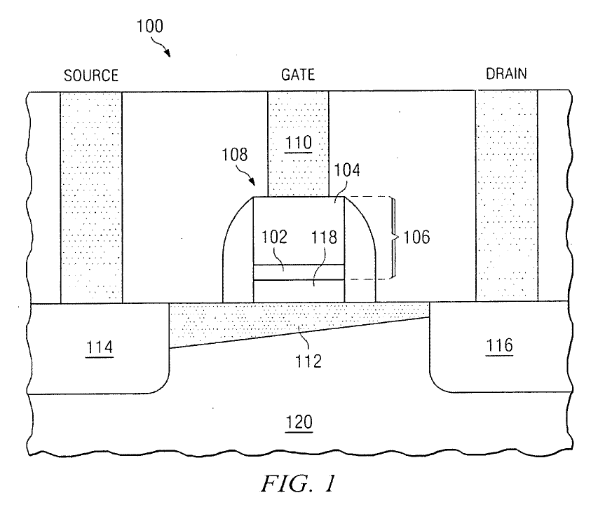

FIG. 1 illustrates a CMOS transistor fabricated according to the present invention. The transistor of FIG. 1 comprises a stacked gate structure formed on a semiconductor substrate 120. A first layer of gate electrode material 102 (first gate electrode layer) and a second layer of gate electrode material 104 (second gate electrode layer) cumulatively form a single layer of gate electrode material 106 which comprises a gate electrode 108 through which voltage is applied by way of a conductive contact 110. The gate electrode 108 controls the flow of current through the underlying channel 112 between the source 114 and the drain 116 of the semiconductor device in the same manner of operation as a gate dielectric electrode formed from a single CVD deposition of gate electrode material. However the semiconductor device of FIG. 1 offers an improved performance and reliability.

Referring again to FIG. 1, a gate dielectric layer 118 (e.g., gate oxide layer) is configured above the semiconductor substrate 120. It will be appreciated that the gate dielectric layer 118 may be comprised of a wide range of materials. In various embodiments, the gate dielectric layer 118 comprises SiO₂, SiON, a high k-material, or a stack of SiO₂/high-k or SiON/high-k. The high-k material may further comprise a broad range of dielectrics including hafnium based dielectrics (hafnium oxide (HfO₂), hafnium silicate (HfSiO), halfnium silicon oxynitride (HfSiON)), zirconium based dielectrics (Zirconium oxide (ZrO₂), Zirconium silicate (ZrSiO), zirconium silicon oxynitride (ZrSiON)), lanthanum based dielectrics, etc.

The gate electrode 108 (e.g., metal gate electrode), comprising a first physically deposited gate electrode layer 102 and a second chemically deposited cap layer 104, is configured above the gate dielectric layer 118. The gate electrode 108 may be comprised of a wide variety of materials including Si, SiGe, and metal electrodes (e.g., titanium (Ti), titanium nitride (TiN), titanium aluminum nitride (TiAlN), titanium silicon nitride (TiSiN), tungsten (W), tungsten nitride (WN), Molybdenum (Mo), tantalum (Ta), tantalum nitride (TaN), tantalum aluminum nitride (TaAlN), ruthenium (Ru), ruthenium oxide (RuO₂), tantalum silicon nitride (TaSiN), ruthenium tantalum nitride (RuTaN), etc.).

The first gate electrode layer is formed onto the surface of a gate dielectric material using a non-damaging technique. In one embodiment, the first layer is deposited using a physical vapor deposition (PVD) (e.g., sputtering, evaporation, molecular beam epitaxy, e-beam evaporation) thereby resulting in a damage free interface between the gate dielectric material and the gate electrode material. The PVD deposition forms a first gate electrode layer on the gate dielectric material without introducing unwanted impurities (e.g., hydrogen, oxygen, carbon, etc.) into the system. In one embodiment, the first layer of gate electrode material is formed to a thickness between 3 Å and 200 Å. In alternative embodiments, the layer of gate electrode thickness may be formed to other thicknesses depending on process requirements.

A second gate electrode layer is then formed onto the first layer of gate electrode material by chemical deposition process. In one embodiment, the chemical deposition process comprises atomic layer deposition (ALD). In an alternative embodiment, the chemical deposition process comprises chemical vapor deposition (CVD) (e.g., low pressure chemical vapor deposition, plasma enhanced chemical vapor deposition, etc.), for example. The second gate electrode layer can be deposited using mixtures of gas containing impurities which may be harmful to the gate dielectric material (e.g., SiH₄) without causing damage to the gate dielectric since the first gate electrode layer separates the gate dielectric from the CVD environment. The second gate electrode layer is substantially thicker than the first layer of gate electrode material.

The deposition of two distinct gate electrode layers provides a high degree of control to the deposition process without compromising device integrity. For example, in one embodiment the first gate electrode layer is deposited using a physical means to form a first gate electrode layer without damaging the underlying gate dielectric layer. The second gate electrode layer is then deposited by chemical means and can be used to introduce control metal atoms or to set the work function of the transistor. Therefore, the second layer provides impurity control without disturbing the gate dielectric/gate electrode interface.

The first and second deposited layers can often be physically distinguished according to their compositions. For example, if the physically deposited layer is formed by means of a plasma process the physically deposited layer comprises a trace element which is used to initiate the plasma and therefore is deposited within the layer during the deposition. In one embodiment, the trace element comprises argon and therefore the physically deposited layer comprises argon. In another embodiment, the chemically deposited layer is doped (e.g., with oxygen). Therefore, there is a distinct difference between the composition of the physically deposited layer and the chemically deposited layer.

One skilled in the art would appreciated that differentiation in composition between the first and the second gate electrode layers can be achieved by a wide range of experimental procedures. For example, a high resolution Rutherford backscattering, a energy dispersive X-ray analysis, or a electron elastic loss spectroscopic measurement can be taken on the cross section of a deposited gate electrode to determine the composition of the gate electrode

Because PMOS and NMOS transistors function differently, it is desirable to fabricate PMOS and NMOS transistors having gates of different work functions. Generally, this is obtained by using different metal gates (e.g., metal gates doped differently) on the PMOS and NMOS transistors.

In one embodiment, the CMOS transistors provided herein comprises a NMOS device. The NMOS device is configured to control its work function through a chemically deposited gate electrode layer that has some predetermined level of impurity in it. For example, in one embodiment, a CVD NMOS cap is doped with hydrogen (e.g., hydrogen doped metal) such that the hydrogen drives the chemical potential of oxygen in a manner that removes oxygen from the interface between the physically deposited gate electrode layer and the gate dielectric in NMOS devices. In an alternative embodiment, a CVD NMOS cap comprises a metal rich gate electrode (e.g., metal rich metal compound) so that it provides additional metal atoms to the interface between the physically deposited gate electrode layer and the gate dielectric in NMOS devices (i.e., hydrogen can be incorporated at the interface between the gate dielectric layer and the gate electrode metal).

In an alternative embodiment, the CMOS transistor provided herein comprises a PMOS device. The PMOS device is configured to control its work function through a chemically deposited gate electrode layer comprising a predetermined level of impurity. In one embodiment, a CVD NMOS cap provides a level of oxygen impurity to the interface between the PVD metal and the gate dielectric layer resulting in a desirable PMOS work function. In one particular embodiment, the oxygen comprising metal comprises oxygen doped titanium nitride (TiN). In an alternative embodiment, the oxygen comprising metal comprises oxygen doped hafnium carbide (HfC).

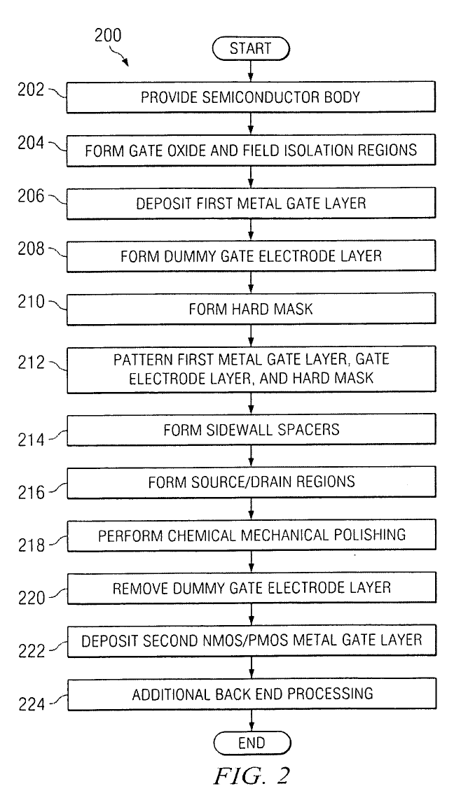

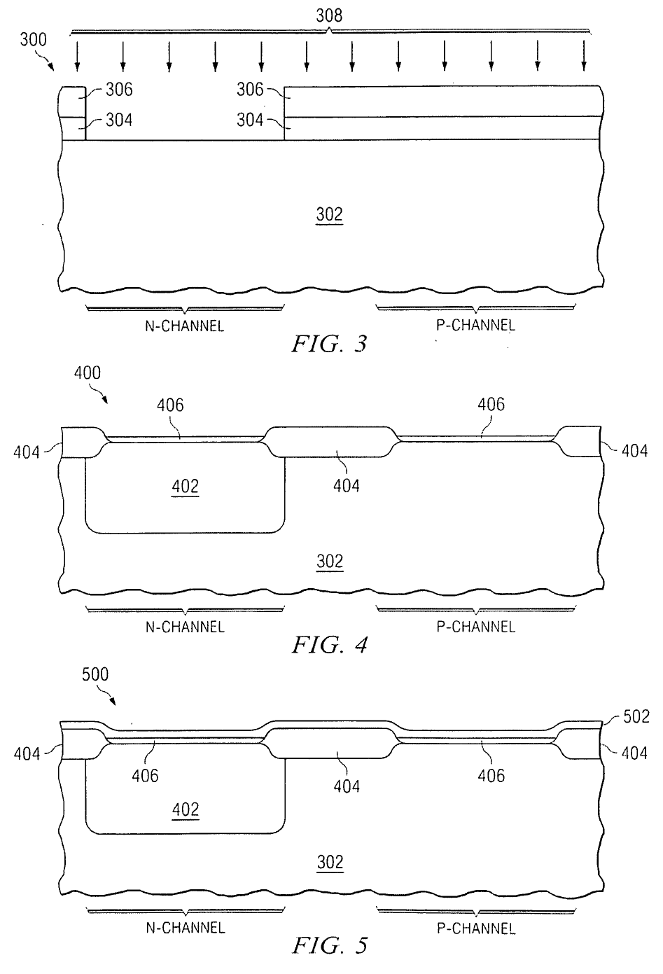

FIG. 2 illustrates a method for forming a gate electrode formation as provided herein. The method of FIG. 2 utilizes a two step gate electrode deposition to form a gate electrode without causing damages to an underlying gate dielectric material. A first gate electrode layer is formed on a gate dielectric material utilizing a physical deposition process that does not damage the underlying gate dielectric material. The first gate electrode layer therefore forms a protective layer of gate electrode material on top of the gate dielectric layer. A second gate electrode layer is then formed utilizing a chemical deposition process. The chemical deposition process produces a gate electrode material with good impurity control and layer uniformity. The first and second gate electrode layer are then selectively patterned and etched to form a gate electrode. FIGS. 3-11 illustrate the actions of method 200.

It will be appreciated that lithography can be implemented to affect much of the patterning and processing described herein, where lithography broadly refers to processes for transferring one or more patterns between various media. In lithography, a light sensitive resist coating is formed over one or more layers to which a pattern is to be transferred. The resist coating is then patterned by exposing it to one or more types of radiation or light which (selectively) passes through an intervening lithography mask to form the pattern. The light causes exposed or unexposed portions of the resist coating to become more or less soluble, depending on the type of resist used. A developer is then used to remove the more soluble areas leaving the patterned resist. The patterned resist can then serve as a mask for the underlying layer or layers which can be selectively treated (e.g., doped).

While method 200 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the disclosure herein. Also, one or more of the acts depicted herein may be carried out in one or more separate acts and/or phases.

At 202 a semiconductor substrate is provided. The substrate may comprise any type of semiconductor body (e.g., silicon, SiGe, SOI, GOI) such as a semiconductor wafer or one or more die on a wafer, as well as any other type of semiconductor and/or epitaxial layers formed thereon and/or otherwise associated therewith. In alternative embodiments, the semiconductor body may further comprise some front end structures (e.g., buried layers, EPI layers, III-V compounds, etc.).

FIG. 3 illustrates a semiconductor body 302 configured to comprise an n-channel and a p-channel device. The semiconductor body 302 is covered with a field oxide 304 (e.g., silicon oxide (SiO₂) formed by a thermal oxidation of the semiconductor body). The field oxide is patterned using standard lithography techniques (e.g., masking with photoresist 306) to form a patterned layer of field oxide 304 which selectively masks the semiconductor body 302, thereby allowing the formation of semiconductor devices having different channel conductivities (e.g., an n-channel device in a p type semiconductor body). As shown in FIGS. 3 and 4, a p-well 402 is formed at the opening of the field oxide 304 which defines n-channel devices. In one embodiment, the p-well 402 is formed by introducing dopants at the surface of the semiconductor substrate 302 and performing a high temperature thermal drive in to diffuse the dopants into the underlying substrate.

Gate oxide and one or more field oxide isolation regions are formed onto the surface of the semiconductor body at 204. Field oxide isolation regions 404 (e.g., STI) can be formed in the substrate prior to forming the layer of gate oxide material. Such field oxide isolation regions 404 are formed at select locations in the semiconductor substrate 302, and serve to separate structures from one another, such as resulting transistors, for example. In one embodiment, the field oxide isolation regions 404 are formed by selectively masking the surface of the semiconductor substrate 302 and performing a high temperature thermal anneal.

The gate oxide material 406 varies in thickness and can be formed to a thickness of about 1 nanometer or more. In one embodiment, the gate oxide material 406 has an equivalent oxide thickness (EOT) of between about 0.5 nanometers and about 3 nanometers, for example. The layer of gate dielectric material comprise a high-k dielectric material, for example. A high-k dielectric material having a k of about 8 and a thickness of about 10 nm, for example, is substantially electrically equivalent to an oxide gate dielectric having a k of about 4 and a thickness of about 5 nm. The layer of gate dielectric material may include, for example, any one or more of the following, either alone or in combination: aluminum oxide (Al₂O₃), zirconium silicate, hafnium silicate, hafnium silicon oxynitride, hafnium oxynitride, zirconium oxynitride, zirconium silicon oxynitride, hafnium lanthanum oxide, hafnium lanthanum oxynitride, etc.

In one embodiment, the gate oxide comprises a Silicon dioxide (SiO₂) layer formed in a rapid thermal processing of a silicon semiconductor body in an oxygen environment. A gate oxide can be formed to a thickness of about 10 nm through a thermal oxidation method at a temperature of about 900° C. and a time of 10 to 15 minutes. In alternative embodiments, the field oxide may be deposited using chemical vapor deposition of alternative oxides such as aluminum oxide (Al₂O₃), titanium oxide (TiO₂), etc. In such embodiments, the oxide can be deposited using PECVD procedures with TEOS or SiH₄ as a source, for example.

At 206 a first gate electrode layer (e.g., first metal gate layer) is deposited onto the surface of the gate dielectric material using a physical deposition means. In one embodiment, illustrated in FIG. 5, the first gate electrode material 502 is deposited as a thin layer over the entire surface of the semiconductor body 302.

The first layer of gate electrode material 502 can be formed by a wide variety of physical deposition means. In one embodiment, physical vapor deposition (PVD) is used to form the first gate electrode layer 502. PVD is performed by placing a solid source metal (e.g., TiN, Ti, TiSiN, TiAlN, W, WN, Mo, Ta, TaN, TaSiN, TaAlN, etc.) and a semiconductor substrate into a vacuum system. The vacuum system is kept at a low pressure (e.g., 10⁻⁶ torr) through use of a vacuum pump (e.g., cryopump, ion pump, turbopump, diffusion pump, etc.). The lower pressure serves to lower the evaporation point of the gate electrode material and to avoid contamination of the semiconductor body. The source metal is then converted from a solid into a vapor by physical means (e.g., high temperature, laser). The vapor is transported across a region of low pressure from the source to the semiconductor substrate, where the vapor undergoes condensation on the semiconductor substrate to form a thin film. Common methods of PVD include sputtering (atoms are dislodged as a result of collisions between the source material and high-energy particles) and evaporation (source material is heated to a temperature at which it undergoes evaporation).

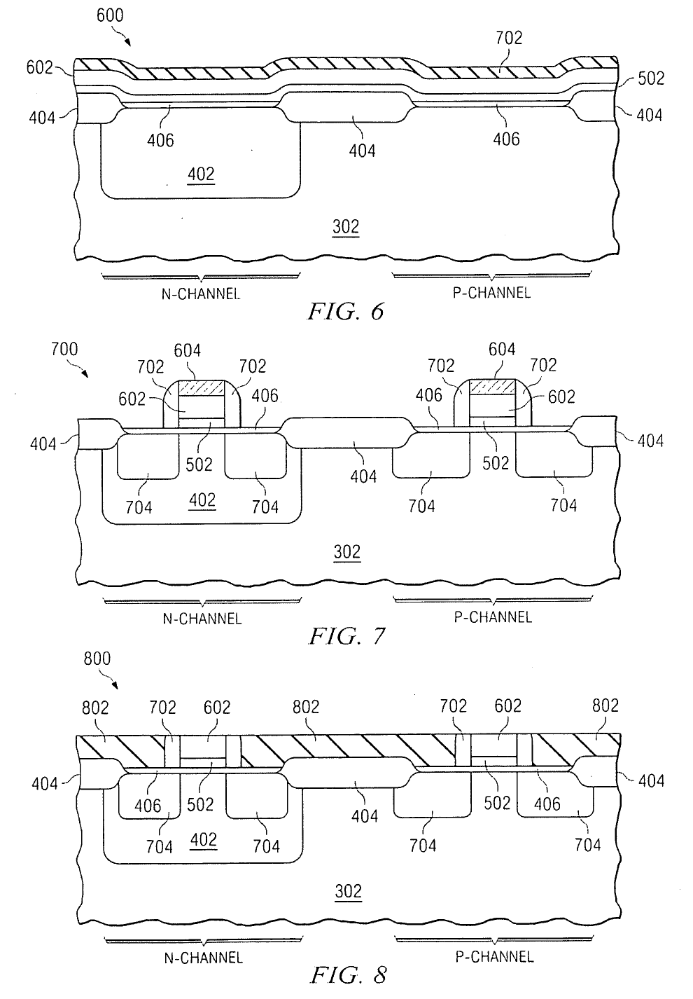

A dummy gate electrode layer is deposited at 208 onto the surface of the first gate electrode layer. In one embodiment, the dummy gate electrode layer 602 (FIG. 6) is comprised of polysilicon. The dummy gate electrode layer 602 can be formed to varying thicknesses. In one embodiment, the dummy gate electrode layer 602 is formed by depositing polysilicon to a thickness of 1500 to 3000 Angstrom.

At 210 a hard mask material is deposited onto the surface of the dummy gate layer. The hard mask 604 may be, for example, around 50 to 500 nm thick and, for example, comprises TiAlN, TiN, Ti, TiO₂, Al, AlOx, AlN, TiAl, TiAlOx, Ta, TaOx, TaN, Cr, CrN, CrOx, Zr, ZrOx, ZrN, Hf, HfN, HfOx, silicon-rich nitride (SRN), silicon-rich oxynitride (SRON), silicon oxide, low-k dielectric, or any stack or combination thereof. An example of a hard mask stack is 300 nm of PECVD deposited SiO₂ on 50 nm of sputter deposited TiAlN or TiN.

The deposition of the hard mask 604 may comprise a single or multi-layer stack of different materials in order to better control the hard mask profile and remaining hard mask thickness. For example, a hard mask stack is 30 nm of TiAlN on 120 nm of TiAl, which is formed on 20 nm TiAlO which is formed on 50 nm of TiAlN. All of these layers are, for example, deposited by sputter deposition in the same chamber where the film composition is changed during the deposition by varying the gas composition (Ar+N₂ (50/50) for nitride, Ar for metal, and Ar+O₂ (90/10) or Ar+N₂+O₂ (85/10/5) for oxide). The TiAlN is, for example, deposited at around 400 C with high power to achieve roughly 100 nm/min TiAlN deposition rate. The TiAlN can be replaced by TiN for all of these cases.

The first gate electrode layer, the dummy gate electrode layer, and the hard mask are selectively patterned at 212. The first gate electrode layer (e.g., first metal gate layer), the dummy gate electrode layer and the hard mask layer are patterned to form a dummy gate structure. The use of dummy gate structures allows lithography techniques to achieve a small critical dimensions otherwise not printable and then later to perform a gate replacement of the dummy gate electrode layer with a second gate electrode layer. In one embodiment the first gate electrode layer 502, the dummy gate electrode layer 602, and the hard mask 604 are selectively patterned by covering selected regions of the hard mask with a masking material (e.g., photoresist) and selectively etching the regions that are not covered. For example, a photoresist can be formed over the entire substrate and patterned in accordance with lithographic techniques so that an exposed portion of the semiconductor substrate 302 can be selectively etched. The photoresist is formed to a thickness sufficient to protect masked regions of the substrate from etching.

Sidewall spacers (gate spacers) are formed at 214. Sidewall spacers 702 (FIG. 7) are formed by a blanket deposition of a sidewall spacer material over an entire area of the semiconductor substrate 302 followed by an isotropic etch back of the deposited sidewall spacer material. In one embodiment, the sidewall spacers are formed by depositing a nitride layer on both sidewalls of the gate stack comprising the first gate electrode layer 502, the dummy gate electrode layer 602, and the hard mask 604.

At 216 source and drain regions are formed in the surface of the substrate. In one embodiment, the source and the drain regions 704 (FIG. 7) are self-aligned with the sidewall spacers 702 of the gate structure. For NMOS devices, the implant for the source and drain regions 704 uses n-type impurities such as arsenic or phosphorous. For PMOS devices, the implant for the source and drain regions 704 uses p-type impurities such as indium or boron. Implants for the source and drain regions 704 are typically performed at an energy of between about 1 KeV and 100 KeV and an impurity concentration of between about 1E15 atoms/cm² and 8E15 atoms/cm². Impurity implants that have been performed into the surface of the semiconductor substrate 302 for the creation of source and drain regions 704 can further be activated (further driven into the surface of the substrate) by performing a rapid thermal anneal after the implant has been completed.

At 218 chemical mechanical polishing (CMP) is performed on the semiconductor substrate 302. As shown in FIG. 8, an inter-level dielectric layer material 802 is deposited onto the surface of the semiconductor. In one embodiment, the semiconductor substrate 302, comprising the first gate electrode layer 502, the dummy gate electrode layer 602, and the hard mask 604, is polished down to the surface of the dummy gate electrode layer 602, thereby removing the hard mask 604. In an alternative embodiment, the CMP process is selectively stopped on the hard mask and the hard mask removal is performed using a dry etch process with equal selectivities to all exposed materials.

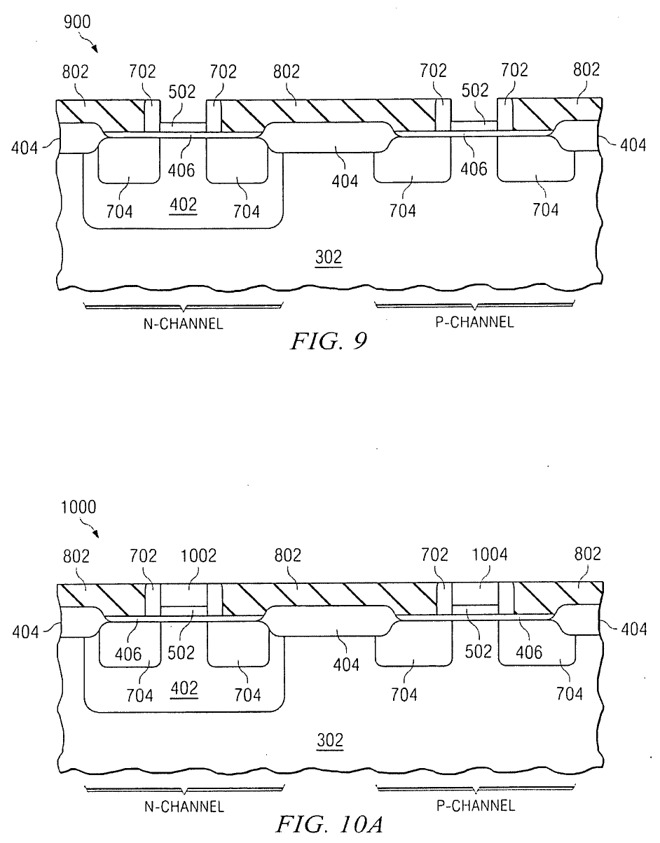

The dummy gate electrode material is removed at 220. The dummy gate electrode layer 602 can be removed according to conventional methods. In one embodiment, a dummy gate electrode layer 602 comprising polysilicon is removed by a plasma etch using chlorine as a reactant gas. FIG. 9 illustrates a cross sectional view of the semiconductor device after the gate electrode material has been removed in the N-channel and P-channel devices.

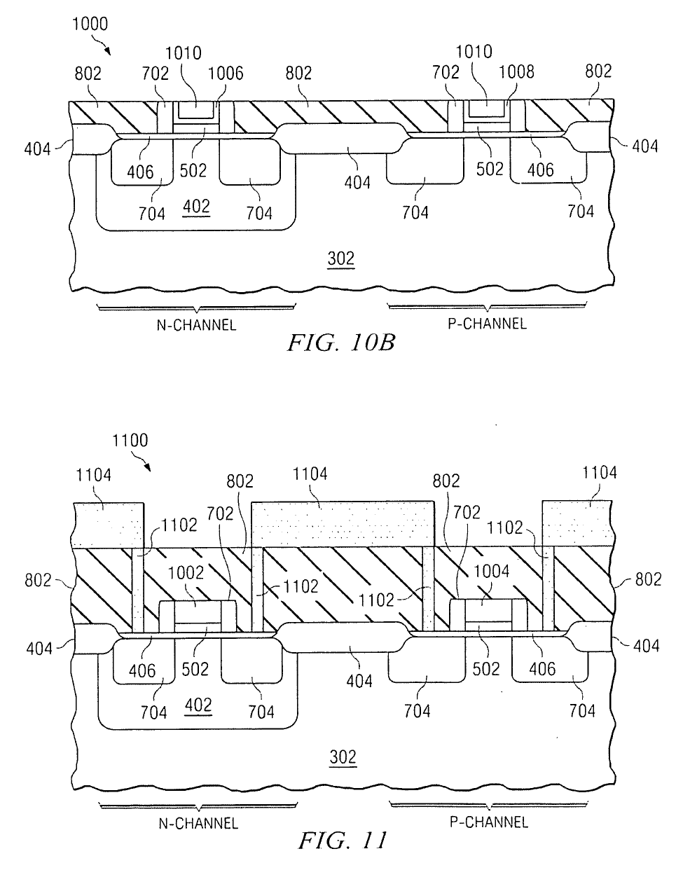

At 222 a second gate electrode layer (e.g., second gate metal layer) is formed on the first layer of gate electrode material. The second gate electrode layer has a substantially larger thickness than the first gate dielectric layer and forms the bulk of the deposited gate electrode material. In one embodiment, different metals (e.g., metal gates doped differently) are deposited on the PMOS and NMOS transistors, to form transistors having gates with desirable PMOS and NMOS work functions. FIG. 10A illustrates a NMOS second gate electrode layer 1002 and a PMOS second gate electrode layer 1004 formed on the first layer of gate electrode material.

In an alternative embodiment, the second gate electrode is deposited to a thickness that does not completely fill the region of the removed dummy gate electrode material. In such an embodiment, shown in FIG. 10B, a second gate electrode layer, comprising a first type of metal 1006 (e.g., TiN_{x<1}), is formed by chemical means (e.g., CVD or ALD) above the first gate electrode layer in the region of removed dummy gate electrode material associated with the NMOS device (e.g., TiN_{x<1} is blanket deposited over the surface of the substrate and selectively etched to remove it from PMOS device regions). Similarly, a second gate electrode layer, comprising a second type of metal 1008 (e.g., TiNO), is formed by chemical means (e.g., CVD or ALD) above the first gate electrode layer in the region of removed dummy gate electrode material associated with the PMOS device (e.g., TiNO is blanket deposited over the surface of the substrate and selectively etched to remove it from NMOS device regions). A separate metal fill process then forms a metal fill layer 1010, comprising a conductive material (e.g., Tungsten (W) or Aluminum (Al)), that is configured above the second gate electrode layer and which completes the gate electrode for both the NMOS and PMOS devices. In one additional embodiment, a high temperature thermal anneal (e.g., 300-600° C.) can be performed once the second gate electrode layer (e.g., comprising the first type of metal 1006 and the second type of metal 1008) is deposited. In another additional embodiment, a CMP process is performed to remove excess metal fill 1010.

The second gate electrode layer (1002, 1004) can be formed by a wide variety of chemical deposition means. In one embodiment, the second gate electrode metal layer (1002, 1004) is formed by adding a predetermined hydrogen impurity into the reaction chamber during the chemical deposition. Incorporation of the predetermined hydrogen impurity into the reaction chamber causes the deposited layer to comprise a level of hydrogen which drives the chemical potential of oxygen to remove oxygen from the interface between the PVD metal and the dielectric thereby forming a desirable PMOS work function.

In an alternative embodiment, the second gate electrode metal layer (1002, 1004) is formed by adding a predetermined oxygen impurity into the reaction chamber during the chemical deposition. Incorporation of the predetermined oxygen impurity into the reaction chamber causes the deposited layer to comprise a level of oxygen which results in a desirable PMOS work function. In one embodiment the oxygen comprising metal comprises oxygen doped titanium nitride (TiN). In an alternative embodiment, the oxygen comprising metal comprises oxygen doped hafnium carbide (HfC).

At 224 further back end processing is performed. Back end of the line processing may comprise the formation a plurality of conductive layers (e.g., copper metal layers) which form a robust system of electrical connections between the semiconductor devices and the outside world (e.g., packaging leads). In one embodiment the electrical connections comprise tungsten contacts 1102 embedded in an inter-level dielectric layer 802. The contacts 1102 connect a semiconductor device's source and drain regions 704 to a first copper metal level 1104. The first copper metal level 1104 can subsequently be connecting additional metal levels (not shown) to form a complex configuration of copper metal levels of varying thicknesses and heights formed in a plurality of dielectric layers.

As provided in method 200, reduction of damage at the interface of the gate dielectric material and the gate electrode material allows the deposition of a metal gate onto an underlying gate dielectric (e.g., gate oxide) material with reduced electrical thickness due to a more precise control of the gate dielectric formation with respect to single CVD deposition methods. Therefore, the method provided herein provides a high quality gate electrode material without damaging the underlying gate electrode material. The resulting gate dielectric material allows for correct flat band and threshold voltage offsets by incorporating controlled impurities to optimize work function setting. It furthermore results in an improvement in device characteristics and integrated chip reliability.

Although the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. A semiconductor device comprising:
a semiconductor substrate;
a gate dielectric layer configured above the semiconductor substrate at a first interface;
a gate electrode layer configured above the gate dielectric layer at a second interface, wherein the gate electrode layer comprises a stack of gate electrode layers, comprising:
a first gate electrode layer configured on the gate dielectric layer;
a second gate electrode layer configured above the first gate electrode layer, wherein the first and the second gate electrode layers comprise different chemical impurities.

2. The semiconductor structure of claim 1, wherein the gate electrode comprises TiN, Ti, TiAlN, TiSiN, W, WN, WSiN, Mo, Ta, TaN, TaSin, TaAlN, Ru, RuO₂, or RuTaN.

3. The semiconductor structure of claim 1, wherein the first gate electrode layer comprises argon.

4. The semiconductor structure of claim 1, wherein the second gate electrode layer comprises an oxygen doped metal, which provides a level of oxygen impurity to the second interface sufficient to provide a desirable PMOS work function.

5. The semiconductor structure of claim 1, wherein the second gate electrode layer comprises a hydrogen doped metal, which provides a level of hydrogen impurity to the second interface sufficient to provide a desirable NMOS work function.

6. The semiconductor structure of claim 1, wherein the second gate electrode layer comprises a metal rich metal compound configured to incorporate metal rich atoms at the second interface thereby setting a desirable NMOS work function for an associated device.

7. A method for forming a gate electrode material without damaging an underlying gate oxide layer, comprising:
providing a semiconductor substrate;
forming a gate oxide layer on the semiconductor substrate;
depositing a first gate electrode layer onto the gate oxide layer by a physical deposition process which does not damage the underlying gate oxide layer; and
depositing a second gate electrode layer onto the first gate electrode layer by a chemical deposition process, wherein the first and the second gate electrode layers comprise different chemical impurities;
wherein the first and the second gate electrode layers form a gate electrode configured to control current flow in a charge carrying channel located beneath the gate oxide layer.

8. The method of claim 7, wherein the second gate electrode layer is substantially thicker than the first gate electrode layer.

9. The method of claim 8, further comprising forming one or more field oxide isolation regions within the semiconductor substrate.

10. The method of claim 8, further comprising:
depositing a dummy gate electrode layer above the first gate electrode layer;
forming a hard mask above the dummy gate electrode layer;
selectively patterning the first gate electrode layer, the dummy gate electrode layer, and the hard mask to form a dummy gate structure; and
removing the dummy gate electrode layer prior to depositing the second gate electrode layer.

11. The method of claim 10, further comprising depositing a metal fill layer configured to completely fill the region previously occupied by the dummy gate electrode layer, wherein the metal fill layer comprises a conductive material formed above the second gate electrode layer.

12. The method of claim 10, further comprising performing chemical mechanical polishing to remove the hard mask prior to removing the dummy gate electrode layer.

13. The method of claim 10, further comprising:
performing a chemical mechanical polishing process that selectively stops on the hard mask; and
removing the hard mask using a dry etch process prior to removing the dummy gate electrode layer.

14. The method of claim 10, further comprising forming sidewall spacers abutting sidewalls of the dummy gate structure.

15. The method of claim 7, wherein physical means comprises sputtering, evaporation, e-beam evaporation, or molecular beam epitaxy.

16. The method of claim 7, wherein chemical means comprises low pressure chemical vapor deposition, plasma enhanced chemical vapor deposition, or atomic layer deposition.

17. The method of claim 7, wherein the second gate electrode layer comprises an oxygen doped metal, which provides a level of oxygen impurity sufficient to provide a desirable PMOS work function to an interface between the gate oxide layer and the first gate electrode layer.

18. The method of claim 7, wherein the second gate electrode layer comprises a hydrogen doped metal, which provides a level of hydrogen impurity sufficient to provide a desirable NMOS work function to an interface between the gate oxide layer and the first gate electrode layer.

19. The method of claim 7, wherein the second gate electrode layer comprises a metal rich metal compound configured to incorporate metal rich atoms at an interface between the gate oxide layer and the first gate electrode layer thereby setting a desirable NMOS work function for an associated device.

20. A method for forming a gate electrode material without damaging an underlying gate oxide layer, comprising:
providing a semiconductor substrate;
forming a gate oxide layer on the semiconductor substrate;
forming one or more field oxide isolation regions within the semiconductor substrate;
depositing a first gate electrode layer onto the gate oxide layer by a physical means which does not damage the underlying gate oxide layer;
depositing a dummy gate electrode layer above the first gate electrode layer;
forming a hard mask above the dummy gate electrode layer;
selectively patterning the first gate electrode layer, the dummy gate electrode layer, and the hard mask to form a dummy gate structure;
forming sidewall spacers abutting sidewalls of the dummy gate structure;
forming a source and drain region configured within the semiconductor substrate and extending from below the sidewall spacers away from the first gate electrode layer;
performing chemical mechanical polishing to remove the hard mask;
removing the dummy gate electrode layer; and
depositing a second gate electrode layer onto the first gate electrode layer by a chemical means, wherein the first and the second gate electrode layer comprise different chemical impurities;
and wherein the first and the second gate electrode layers form a gate electrode configured to control current flow in a charge carrying channel located beneath the gate oxide layer.
